(19) United States
(12) Patent Application Publication
(10) Pub. No.: US 2007/0032008 A1
(43) Pub. Date: Feb. 8, 2007

(54) MOS semiconductor devices having polysilicon gate electrodes and high dielectric constant gate dielectric layers and methods of manufacturing such devices

(76) Inventors: Hye-Min Kim, Gyeonggi-do (KR); Yu-Gyun Shin, Gyeonggi-do (KR); In-Sang Jeon, Seoul (KR); Sang-Bom Kang, Seoul (KR); Hong-Bae Park, Seoul (KR); Beom-Jun Jin, Seoul (KR)

Correspondence Address: D. Randal Ayers;Myers Bigel Sibley & Sajovec, P.A., P. O. Box 37428, Raleigh, NC, 27627, US

(21) Appl. No.: 11/494,100

(22) Filed: Jul. 27, 2006

(30) Foreign Application Priority Data
Aug. 8, 2005 (KR) 2005-72422

(51) Int. Cl. H01L 21/8238

(52) U.S. Cl. 438/199

(57) ABSTRACT

A semiconductor device includes a substrate divided into an NMOS region and a PMOS region, a first gate pattern formed on the PMOS region, and a second gate pattern formed on the NMOS region. The first gate pattern includes a first gate oxide layer pattern, a metal oxide layer pattern, a silicon nitride layer pattern and a first polysilicon layer pattern that are sequentially stacked. The second gate pattern includes a second oxide layer pattern and a second polysilicon layer pattern. Related methods are also provided.

### CROSS REFERENCE TO RELATED APPLICATION

This application claims priority under 35 U.S.C. § 119 from Korean Patent Application No. 2005-72422, filed on Aug. 8, 2005, the disclosure of which is hereby incorporated by reference herein as if set forth in its entirety.

### FIELD OF THE INVENTION

The present invention relates to semiconductor devices and, more particularly, to MOS semiconductor devices that include gate dielectric layers having high dielectric constants and to methods of manufacturing such devices.

### BACKGROUND

In order to provide more highly integrated semiconductor devices and/or semiconductor devices with lower operational voltages, the thickness of the gate dielectric layer in many semiconductor devices has been reduced in recent years. However, when the thickness of the gate dielectric layer is reduced to, for example, about 20 Å, the tunneling of electrons through the gate dielectric layer may increase significantly, resulting in increased device leakage currents. As a result, it has been proposed that gate dielectric layers may be formed of materials with a high dielectric constant (i.e., higher than the dielectric constant of silicon oxide) to provide gate dielectric layers with both low leakage currents and a thin equivalent oxide thickness (EOT).

Unfortunately, it has been found that when a polysilicon gate electrode is formed on these high dielectric constant gate dielectric layers, the Fermi level of the gate electrode may be fixed to a constant value. This phenomenon is referred to as Fermi level pinning. When Fermi level pinning occurs, the work function of the polysilicon in the gate electrode is changed in a way that may make it difficult to control the flat band voltage through the doping of impurities. As a result, it may be difficult to form a MOS transistor having a desired threshold voltage. The Fermi level pinning phenomena is particularly pronounced in PMOS transistors, with the Fermi level of the polysilicon in the gate electrode being increased by about 0.4 eV to about 0.6 eV as compared to the Fermi level of a polysilicon gate electrode that is formed on a conventional silicon oxide gate dielectric layer. This increase in the Fermi level may result in a corresponding increase in the threshold voltage of the PMOS transistor by, for example, about 0.4 eV to about 0.6 eV.

When the gate electrode is formed of a metal (as opposed to, for example, polysilicon), it has been reported that the Fermi level pinning phenomena may be reduced. However, the metals that may be appropriate for use as a gate electrode may have a high work function of, for example, about 4.6 eV to about 5.2 eV. As a result, selecting a metal having the above high work function that also exhibits good deposition and etching characteristics may not be easy.

An example of a gate pattern that may exhibit reduced Fermi level pinning is disclosed in U.S. Patent Application Publication No. 2004/00099916. According to the disclosure in the above U.S. Patent Application Publication, germanium silicide is used to form the gate electrodes for PMOS transistors, while silicon germanium is used to form the gate electrodes for NMOS transistors.

Unfortunately, however, complicated processes may be required to form the suicide layers in these transistors. Moreover, the process for silicidating the silicon germanium in the PMOS transistor may involve a high heat treatment that may negatively impact the performance of the device.

### SUMMARY

Pursuant to some embodiments of the present invention, semiconductor devices are provided that include a substrate that has an NMOS region and a PMOS region. A first gate pattern is provided on the PMOS region, and a second gate pattern is provided on the NMOS region. The first gate pattern includes a first gate oxide layer pattern that includes a high dielectric constant material, a metal oxide layer pattern, a silicon nitride layer pattern and a first polysilicon layer pattern that are sequentially stacked on the substrate. The second gate pattern includes a second oxide layer pattern and a second polysilicon layer pattern that are sequentially stacked on the substrate.

In embodiments of the present invention, the gate oxide layer pattern may comprise a pattern formed of an oxide of hafnium and/or zirconium such as, for example, a hafnium oxide (HfO₂) pattern, a hafnium oxynitride (HfOₓN_{y}) pattern, a hafnium silicon oxynitride (HfSiₓO_{y}N_{z}) pattern, a hafnium aluminum oxide (HfAlₓO_{y}) pattern, a zirconium oxide (ZrO₂) pattern, a zirconium oxynitride (ZrOₓN_{y}) pattern, a zirconium silicon oxynitride (ZrSiₓO_{y}N_{z}) pattern and/or a zirconium silicon oxide (ZrSiₓO_{y}) pattern. The first and second gate oxide layer patterns may comprise substantially the same material. The metal oxide layer pattern may comprise an aluminum oxide layer.

Pursuant to further embodiments of the present invention, methods of manufacturing a semiconductor device are provided in which a gate oxide layer that includes a high dielectric constant material is formed on a substrate that is divided into a PMOS region and an NMOS region. A metal oxide layer is formed on the gate oxide layer. A silicon nitride layer is formed on the metal oxide layer. The silicon nitride layer and the metal oxide layer in the NMOS region are selectively removed to form a preliminary metal oxide layer pattern and a preliminary silicon nitride layer pattern. A polysilicon layer is formed on the gate oxide layer, the preliminary metal oxide layer pattern and the preliminary silicon nitride layer pattern. The polysilicon layer, the preliminary silicon nitride layer pattern, the preliminary metal oxide layer pattern and the gate oxide layer are patterned to form a first gate pattern in the PMOS region and a second gate pattern in the NMOS region. The first gate pattern includes a first gate oxide layer pattern, a metal oxide layer pattern, a silicon nitride layer pattern and a first polysilicon layer pattern. The second gate pattern includes a second gate oxide layer pattern and a second polysilicon layer pattern.

According to some embodiments of the present invention, the polysilicon pattern may be formed on a gate dielectric layer pattern having a high dielectric constant so that the Fermi level pinning may be sufficiently reduced. As a result, threshold voltages of a PMOS transistor and an NMOS transistor may be readily controlled.

### BRIEF DESCRIPTION OF THE DRAWINGS

The accompanying drawings, which are included to provide a further understanding of the invention and are incorporated in and constitute a part of this application, illustrate certain embodiment(s) of the invention. In the drawings:

FIG. 1 is a cross-sectional diagram illustrating a semiconductor device in accordance with some embodiments of the present invention;

FIGS. 2-7 are cross-sectional diagrams illustrating methods of manufacturing the semiconductor device in FIG. 1; and

FIGS. 8-10 are cross-sectional diagrams illustrating methods of manufacturing the semiconductor device in FIG. 1 in accordance with further embodiments of the present invention.

### DETAILED DESCRIPTION

The present invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises”, “comprising”, “includes” and/or “including”, when used in this specification, specify the presence of stated features, steps, operations, elements, and/or components, but do not preclude the presence or addition of one or more other features, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

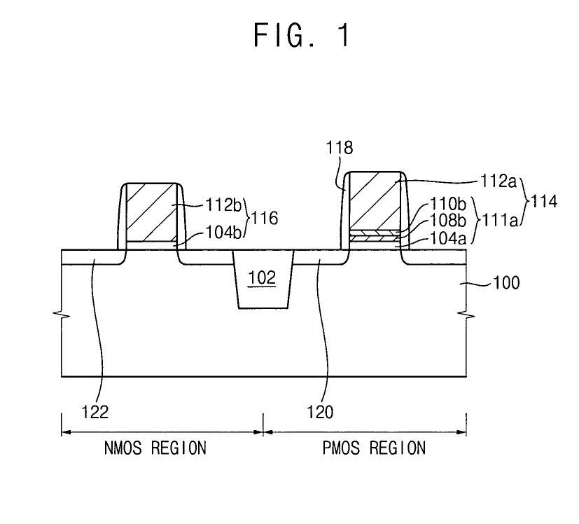

FIG. 1 is a cross-sectional diagram illustrating a semiconductor device in accordance with some embodiments of the present invention. As shown in FIG. 1, a semiconductor substrate 100 is divided into a PMOS region and an NMOS region. The PMOS region and the NMOS region may be defined by an isolation layer pattern 102. The PMOS region is doped with N type impurities. The NMOS region is doped with P type impurities.

A first gate pattern 114 is formed on the PMOS region. The first gate pattern 114 includes a first gate oxide layer pattern 104a, a metal oxide layer pattern 108b, a silicon nitride layer pattern 110b and a first polysilicon layer pattern 112a that are sequentially stacked on the semiconductor substrate 100.

The first gate oxide layer pattern 104a includes a material having a dielectric constant that is higher than the dielectric constant of silicon oxide. Herein, such materials are referred to as “high dielectric constant materials.” In some embodiments of the present invention, the high dielectric constant material may, for example, comprise an oxide that contains hafnium or zirconium (e.g., a hafnium oxide layer (HfO₂), a hafnium oxynitride layer (HfOₓN_{y}), a hafnium silicon oxynitride layer (HfSiₓO_{y}N_{z}), a hafnium aluminum oxide layer (HfAlₓO_{y}), a zirconium oxide layer (ZrO₂), a zirconium oxynitride layer (ZrOₓN_{y}), a zirconium silicon oxynitride layer (ZrSiₓO_{y}N_{z}), a zirconium silicon oxide layer (ZrSiₓO_{y}), etc.). The first gate pattern 104a may comprise one or more of the above-referenced layers.

The metal oxide layer pattern 108b is formed on the first gate oxide layer pattern 104a. The metal oxide layer pattern 108b may suppress Fermi level pinning. An example of a suitable metal oxide layer pattern 108b is an aluminum oxide layer (Al₂O₃).

A PMOS transistor that includes such an aluminum oxide layer on a first gate oxide layer pattern 104a that has the high dielectric constant, and a gate electrode that includes polysilicon, may exhibit an increase in flat band voltage of about 100 mV to about 300 mV compared to the flat band voltage of a PMOS transistor that does not include the aluminum oxide layer. Thus, by including the aluminum oxide layer in the first gate pattern 114, the Fermi level pinning phenomena may be reduced by about 0.1 eV to about 0.3 eV.

The silicon nitride layer pattern 110b is formed on the metal oxide layer pattern 108b. The silicon nitride layer pattern 110b may act as a barrier layer for preventing P-type impurities such as, for example, boron that are doped into the polysilicon layer pattern 112a, from penetrating into the semiconductor substrate 100. The silicon nitride layer pattern 110b may also facilitate suppressing the Fermi level pinning phenomenon.

A laminate structure that includes the first gate oxide layer pattern 104a, the metal oxide layer pattern 108b and the silicon nitride layer pattern 110b is provided as a gate dielectric layer pattern 111a of the PMOS transistor. The first oxide layer pattern 104a, the metal oxide layer pattern 108b and the silicon nitride layer pattern 110b may all be thin layers. In some embodiments of the present invention the silicon nitride layer pattern 110b may be the thinnest of the layers in gate dielectric layer pattern 111a.

The high dielectric constant gate dielectric layer pattern 111a may be used in manufacturing a transistor having a thin EOT. Thus, for example, the gate dielectric layer pattern 111a that includes the first gate oxide layer pattern 104a, the metal oxide layer pattern 108b and the silicon nitride layer pattern 110b may have a thickness of no more than about 100 Å. In certain embodiments of the present invention, the gate dielectric layer pattern 111a may have a thickness of about 30 Å to about 50 Å to provide a gate dielectric layer pattern 111a with an EOT of about 20 Å.

As is also shown in FIG. 1, a second gate pattern 116 is formed on the NMOS region of the semiconductor substrate 100. The second gate pattern 116 includes a second gate oxide layer pattern 104b and a second polysilicon layer pattern 112b. The second gate oxide layer pattern 104b may comprise a material that is substantially the same as that of the first gate oxide layer pattern 104a. The second polysilicon layer pattern 112b is doped with N type impurities. Examples of the N type impurities include arsenic (As), phosphorous (P), etc.

Spacers 118 may be formed on sidewalls of the first and second gate patterns 114 and 116, respectively. First source/drain regions 120 doped with P type impurities are formed in the semiconductor substrate 100 at both sides of the first gate pattern 114. Second source/drain regions 122 doped with N type impurities are formed in the semiconductor substrate 100 at both sides of the second gate pattern 116.

According to some embodiments discussed above, a high dielectric constant material is used to form the gate dielectric layer patterns 111a, 104b of respective PMOS and NMOS transistors that each include a polysilicon gate electrode 112a, 112b. The gate dielectric layer 111a of the PMOS transistor may act to at least partially suppress the Fermi level pinning phenomena. Further, flat band voltages may be obtained for both the PMOS and the NMOS transistors. As a result, the threshold voltages of the PMOS and NMOS transistors may be readily controlled.

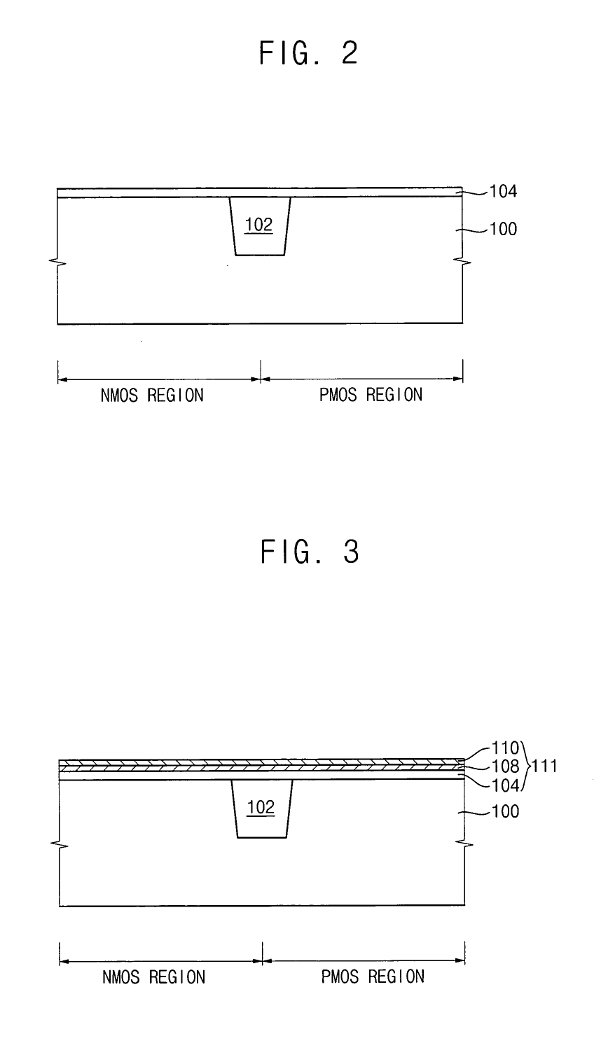

FIGS. 2 to 7 are cross-sectional diagrams illustrating methods of manufacturing the semiconductor device in FIG. 1 in accordance with some embodiments of the present invention.

Referring to FIG. 2, a semiconductor substrate 100 is prepared. Examples of the semiconductor substrate 100 include a single crystalline silicon substrate, a silicon-on-insulator substrate, etc. In the illustrated embodiments, the semiconductor substrate 100 comprises a single crystalline silicon substrate.

The region of the semiconductor substrate 100 where the PMOS transistor is to be formed is doped with N type impurities. The region of the semiconductor substrate 100 where the NMOS transistor is to be formed is doped with P type impurities. Examples of the N type impurities include arsenic, phosphorous, etc. An example of the P type impurities includes boron.

An isolation layer pattern 102 is formed in the semiconductor substrate 100 using, for example, a shallow trench isolation (STI) process to define an active region and a field region of the semiconductor substrate 100. The isolation layer pattern 102 may be formed at an interface between the PMOS region and the NMOS region.

As shown in FIG. 3, a gate oxide layer 104 is formed on the semiconductor substrate 100. The gate oxide layer 104 is formed of a high dielectric constant material such as, for example, an oxide that contains hafnium or zirconium. Pursuant to some embodiments of the present invention, the gate oxide layer 104 may comprise a hafnium oxide layer (HfO₂), a hafnium oxynitride layer (HfOₓN_{y}), a hafnium silicon oxynitride layer (HfSiₓO_{y}N_{z}), a hafnium aluminum oxide layer (HfAlₓO_{y}), a zirconium oxide layer (ZrO₂), a zirconium oxynitride layer (ZrOₓN_{y}), a zirconium silicon oxynitride layer (ZrSiₓO_{y}N_{z}) and/or a zirconium silicon oxide layer (ZrSiₓO_{y}).

The gate oxide layer 104 may be formed by a chemical vapor deposition (CVD) process, an atomic layer deposition (ALD) process, etc. In certain embodiments of the present invention, hafnium silicon oxynitride may be deposited on the semiconductor substrate 100 using an ALD process to form the gate oxide layer 104. A hafnium silicon oxynitride gate oxide layer 104 may be formed, for example, as follows.

A semiconductor substrate 100 is loaded into a chamber. A hafnium source material such as tetrakis diethyl amino hafnium (TDEAH), Hf(OtBu)₄, etc., is introduced into the chamber. A first portion of the hafnium source material is chemisorbed on the semiconductor substrate 100. A second portion of the hafnium source material is physisorbed on the semiconductor substrate 100. A purge gas such as, for example, an argon gas is introduced into the chamber to remove the physisorbed portion of the hafnium source material from the semiconductor substrate 100. An oxidizing agent such as, for example, ozone is then introduced into the chamber. The oxidizing agent reacts with the chemisorbed portion of the hafnium source material to form a first solid material that includes hafnium oxide on the semiconductor substrate 100. A purge gas is introduced into the chamber to remove any remaining oxidizing agent.

A silicon source material such as tetrakis dimethyl amino silicon (TDMAS), tetra methoxy silane (TMOS), etc., may be introduced into the chamber. A first portion of the silicon source material is chemisorbed on the first solid material. A second portion of the silicon source material is physisorbed on the first solid material. A purge gas is introduced into the chamber to remove the physisorbed portion of the silicon source material from the semiconductor substrate 100. An oxidizing agent is introduced into the chamber. The oxidizing agent reacts with the chemisorbed portion of the silicon source material to form a second solid material that includes silicon oxide on the first solid material. A purge gas is introduced into the chamber to remove any remaining portion of the oxidizing agent.

Forming the first and second solid materials is repeated to form a hafnium silicon oxide layer on the semiconductor substrate 100.

The hafnium silicon oxide layer may then be nitrified to convert the hafnium silicon oxide layer into a hafnium silicon oxynitride layer, thereby forming a gate oxide layer 104 that includes hafnium silicon oxynitride. The gate oxide layer 104 may also be thermally treated or treated using plasma to densify and cure the gate oxide layer 104.

As is also shown in FIG. 3, a metal oxide layer 108 is formed on the gate oxide layer 104. The metal oxide layer 108 may suppress the Fermi level pinning phenomenon. As noted above, one example of the metal oxide layer 108 according to embodiments of the present invention is an aluminum oxide layer. The metal oxide layer 108 may be formed, for example, using an ALD process. An exemplary process for forming a metal oxide layer 108 that includes aluminum oxide is as follows.

A semiconductor substrate 100 is loaded into a chamber (or remains in the chamber following the completion of a previous processing step). An aluminum source material such as Al[OCH₃]₃, Al[OC₂H₅]₃, Al[OC₃H₇]₃, etc., is introduced into the chamber. A first portion of the aluminum source material is chemisorbed on the gate oxide layer 104. A second portion of the aluminum source material is physisorbed on the gate oxide layer 104. A purge gas such as, for example, an argon gas is introduced into the chamber to remove the physisorbed portion of the aluminum source material from the gate oxide layer 104. An oxidizing agent such as ozone is then introduced into the chamber. The oxidizing agent reacts with the chemisorbed portion of the aluminum source material to form a solid material that includes aluminum oxide on the gate oxide layer 104. A purge gas is then introduced into the chamber to remove any remaining portion of the oxidizing agent.

Herein, a “cycle” of the ALD process used in forming the metal oxide layer 108 may comprise the steps of (1) introducing the aluminum source material, (2) introducing the purge gas, (3) introducing the oxidizing agent and (4) introducing the purge gas. Performance of this cycle results in the formation of a single aluminum oxide layer. The cycle may be repeated multiple times to form a metal oxide layer 108 that has the desired thickness.

A silicon nitride layer 110 is formed on the metal oxide layer 108. The silicon nitride layer 110 may reduce and/or prevent impurities from penetrating into the semiconductor substrate 100. The silicon nitride layer 110 may also be formed, for example, by an ALD process.

Pursuant to certain embodiments of the present invention, the silicon nitride layer 110 may be formed as follows. First, a silicon source material such as a SiCl₂H₂ (DCS) gas, Si₂Cl₆ (HCD) gas, a SiCl₄ gas, etc., is introduced into a chamber that contains the substrate 100 that has the gate oxide layer 104 and metal oxide layers 108 thereon. A first portion of the silicon source material is chemisorbed on the metal oxide layer 108. A second portion of the silicon source material is physisorbed on the metal oxide layer 108. A purge gas such as, for example, an argon gas is introduced into the chamber to remove the physisorbed portion of the silicon source material from the metal oxide layer 108. An ammonia (NH₃) gas is then introduced into the chamber. The ammonia gas reacts with the chemisorbed portion of the silicon source material to form a solid material that includes aluminum oxide on the metal oxide layer 108. A purge gas is then introduced into the chamber to remove any remaining portion of the ammonia gas.

Herein, a “cycle” of the ALD process for forming the silicon nitride layer 110 may comprise the steps of (1) introducing the silicon source material, (2) introducing the purge gas, (3) introducing the ammonia gas and (4) introducing the purge gas. Performance of this cycle results in the formation of a single silicon nitride layer. This cycle may be repeated multiple times to form a silicon nitride layer 110 having a desired thickness.

As noted above, the gate dielectric layer 111 includes the gate oxide layer 104, the metal oxide layer 108 and the silicon nitride layer 110. The gate oxide layer 111 may have a thickness of less than about 100 Å. In certain embodiments of the present invention, the gate dielectric layer 111 may have a thickness of about 30 Å to about 50 Å to provide the gate dielectric layer 111 with an EOT of about 20 Å.

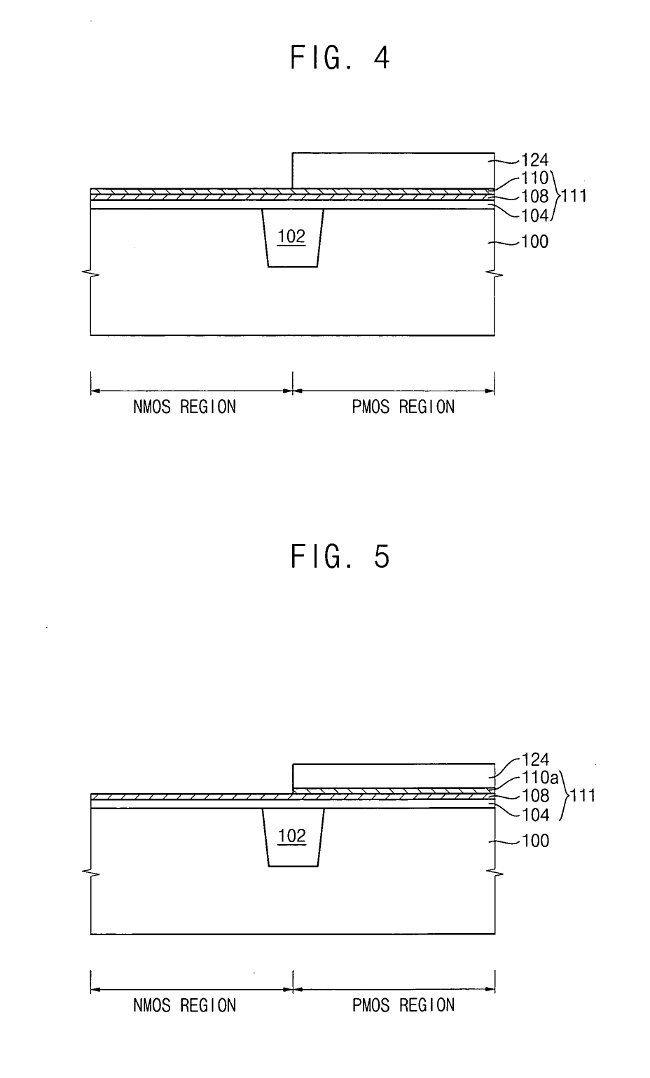

Referring to FIG. 4, a photoresist film (not shown) is formed on the silicon nitride layer 110. The photoresist film may comprise, for example, a photoresist material in a group l-line. The photoresist film is exposed and developed to form a photoresist pattern 124 that selectively exposes the silicon nitride layer 110 in the NMOS region.

As shown in FIG. 5, the silicon nitride layer 110 in the NMOS region may be etched using the photoresist pattern 124 as an etching mask to form a preliminary silicon nitride layer pattern 110a on the PMOS region. If the silicon nitride layer 110 is etched using a dry etching process, damage may occur to one or more of the layers underlying the silicon nitride layer 110 due, for example, to ion impacts. Thus, in embodiments of the present invention, the silicon nitride layer 110 may be removed by a wet etching process. The metal oxide layer 108 may protect the gate oxide layer 104 in the NMOS region during the wet etching process. An example of an etching solution that may be used in the wet etching process is a solution having a content ratio between water and hydro fluoride of about 300:1 to about 1,000:1. The thickness of the photoresist pattern 124 may be reduced during the wet etching process.

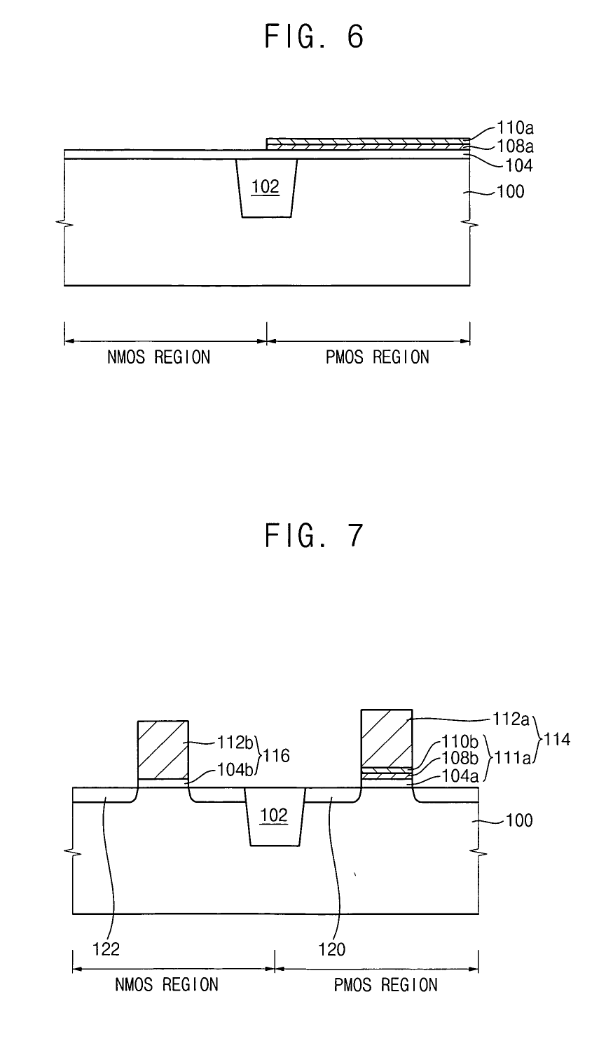

As shown in FIG. 6, the photoresist pattern 124 and the metal oxide layer 108 in the NMOS region may be simultaneously removed to form a preliminary metal oxide layer pattern 108a on the PMOS region. The photoresist pattern 124 may be removed, for example, by an ashing process using oxygen and/or by a stripping process. In other embodiments, the photoresist pattern 124 may be removed using nitrogen and CF₄.

As shown in FIGS. 4-6, the preliminary silicon nitride layer pattern 110a is formed beneath the photoresist pattern 124 in the PMOS region. The preliminary silicon nitride pattern 110a may protect the preliminary metal oxide pattern 108a from damage during the ashing and/or stripping processes.

Referring to FIG. 7, a polysilicon layer (not shown) is formed on the gate oxide layer 104, the preliminary metal oxide layer pattern 108a and the preliminary silicon nitride layer pattern 110a. In the NMOS region, the polysilicon layer is doped with N type impurities such as, for example, arsenic, phosphorous, etc. In the PMOS region, the polysilicon layer is doped with P type impurities such as, for example, boron. The preliminary silicon nitride layer pattern 110a may suppress the penetration of the P type impurities that are in the polysilicon layer in the PMOS region into the semiconductor substrate 100.

The polysilicon layer, the preliminary silicon nitride layer pattern 110a, the preliminary metal oxide layer pattern 108a and the gate oxide layer 104 may then be patterned to form a first gate pattern 114 in the PMOS region and a second gate pattern 116 in the NMOS region. The first gate pattern 114 includes a first gate oxide layer pattern 104a, a metal oxide layer pattern 108b, a silicon nitride layer pattern 110b and a first polysilicon layer pattern 112a that is doped with P type impurities. The second gate pattern 116 includes a second gate oxide layer pattern 104b and a second polysilicon layer pattern 112b that is doped with N type impurities. The first gate oxide layer pattern 104a, the metal oxide layer pattern 108b and the silicon nitride layer pattern 110b together comprise the gate dielectric layer pattern 111a.

Referring to FIG. 1, spacers 118 are formed on sidewalls of the first and second gate patterns 114 and 116, respectively. Further, P type impurities are implanted into the semiconductor substrate 100 at both sides of the first gate pattern 114 to form first source/drain regions 120. N type impurities are implanted into the semiconductor substrate 100 at both sides of the second gate pattern 116 to form second source/drain regions 122.

Thus, according to some embodiments of the present invention, semiconductor devices may be provided that include polysilicon gate electrodes yet have suppressed Fermi level pinning and penetration of impurities. As a result, the threshold voltages of the NMOS and PMOS transistors may be sufficiently controlled so that the semiconductor device may have improved operational characteristics.

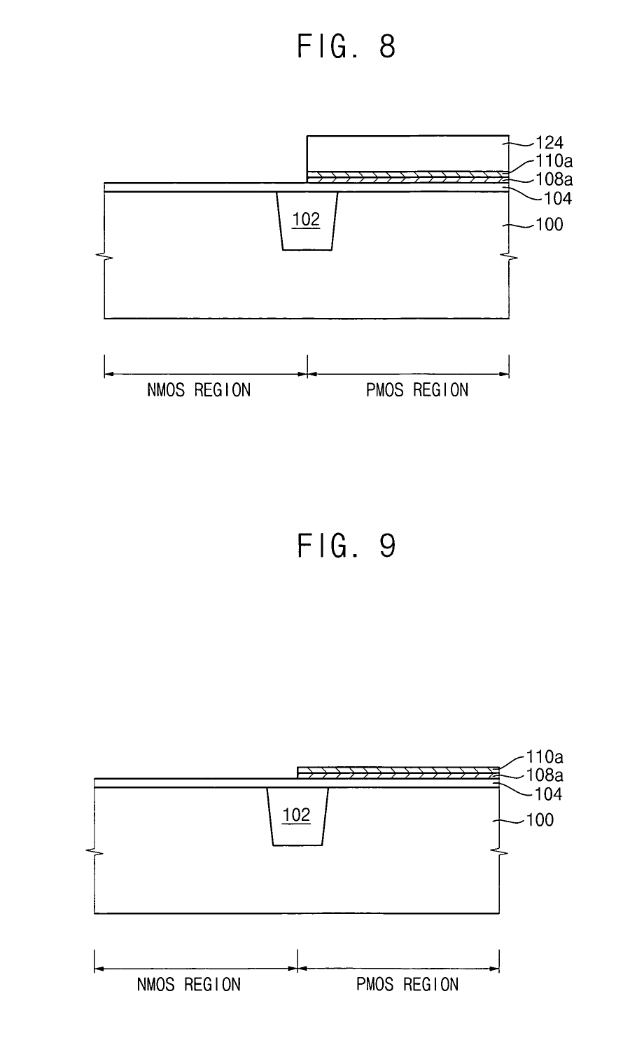

FIGS. 8-10 are cross-sectional diagrams illustrating methods of manufacturing the semiconductor device in FIG. 1 in accordance with further embodiments of the present invention. The methods of these further embodiments are substantially the same as the methods discussed above with reference to FIGS. 2-7 except for the manner in which the thin layers are removed. Thus, in FIGS. 8-10 the same reference numerals are used as in FIGS. 2-7, and processes that are the same is in the methods of FIGS. 2-7 will not be re-described herein.

Referring to FIG. 8, processes are carried out in the same manner as those illustrated with reference to FIGS. 2-4 to form the gate oxide layer 104, the metal oxide layer 108 and the silicon nitride layer 110. The photoresist pattern 124, for selectively exposing the NMOS region, is formed on the silicon nitride layer 110.

The silicon nitride layer 110 in the NMOS region is etched using the photoresist pattern 124 as an etching mask to form a preliminary silicon nitride layer pattern 110a on the PMOS region. The silicon nitride layer 110 may be removed, for example, by a wet etching process.

The metal oxide layer 108 is etched using the photoresist pattern 124 as an etching mask to form a preliminary metal oxide layer pattern 108a. The photoresist pattern 124 may be removed by a wet etching process.

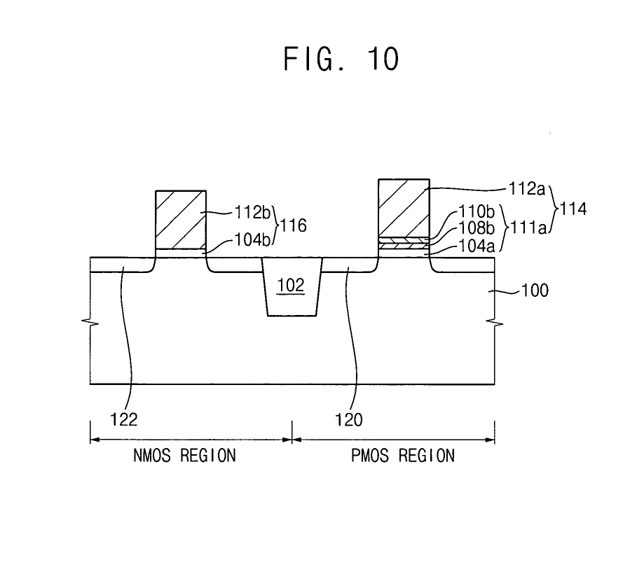

As shown in FIG. 9, the photoresist pattern 124 may be removed using, for example, an ashing process using oxygen and/or a stripping process. In other embodiments, the photoresist pattern 124 may be removed using nitrogen and CF₄.

The preliminary silicon nitride layer pattern 110a may protect the preliminary metal oxide pattern 108a in the PMOS region during the ashing and/or stripping processes.

Referring to FIG. 10, a polysilicon layer (not shown) is formed on the gate oxide layer 104, the preliminary metal oxide layer pattern 108a and the preliminary silicon nitride layer pattern 110a. The polysilicon layer, the preliminary silicon nitride layer pattern 110a, the preliminary metal oxide layer pattern 108a and the gate oxide layer 104 are patterned to form a first gate pattern 114 in the PMOS region and a second gate pattern 116 in the NMOS region. The first gate pattern 114 includes a first gate oxide layer pattern 104a, a metal oxide layer pattern 108b, a silicon nitride layer pattern 110b and a first polysilicon layer pattern 112a that is doped with P type impurities. The second gate pattern 116 includes a second gate oxide layer pattern 104b and a second polysilicon layer pattern 112b that is doped with N type impurities.

The processes for forming the polysilicon layer and for patterning the above-mentioned layers may be substantially the same as those illustrated with reference to FIG. 7.

Referring to FIG. 1, spacers 118 are formed on sidewalls of the first and second gate patterns 114 and 116, respectively. P type impurities are implanted into the semiconductor substrate 100 at both sides of the first gate pattern 114 to form first source/drain regions 120. N type impurities are implanted into the semiconductor substrate 100 at both sides of the second gate pattern 116 to form second source/drain regions 122.

According to some embodiments of the present invention, semiconductor devices are provided having gate patterns that may suppress Fermi level pinning and/or the penetration of impurities into the semiconductor substrate. Moreover, the semiconductor devices may include a polysilicon gate electrode, which may allow subsequent processing steps to be readily carried out. The threshold voltages of the PMOS and NMOS transistors according to some embodiments of the present invention may be readily controlled.

Having described certain embodiments of the present invention, it is noted that modifications and variations can be made by persons skilled in the art in light of the above teachings. It is therefore to be understood that changes may be made to the particular embodiments of the present invention disclosed herein which would be within the scope and the spirit of the invention, as outlined by the appended claims.

What is claimed is:

1. A semiconductor device comprising:
a substrate having a PMOS region and an NMOS region;
a first gate pattern on the PMOS region, the first gate pattern including a first gate oxide layer pattern that includes a high dielectric constant material, a metal oxide layer pattern, a silicon nitride layer pattern and a first polysilicon layer pattern that are sequentially stacked on the substrate; and
a second gate pattern on the NMOS region, the second gate pattern including a second gate oxide layer pattern and a second polysilicon layer pattern that are sequentially stacked on the substrate.

2. The semiconductor device of claim 1, wherein the first and second gate oxide patterns comprise at least one of a hafnium oxide (HfO₂) pattern, a hafnium oxynitride (HfOₓN_{y}) pattern, a hafnium silicon oxynitride (HfSiₓO_{y}N_{z}) pattern, a hafnium aluminum oxide (HfAlₓO_{y}) pattern, a zirconium oxide (ZrO₂) pattern, a zirconium oxynitride (ZrOₓN_{y}) pattern, a zirconium silicon oxynitride (ZrSiₓO_{y}N_{z}) pattern and/or a zirconium silicon oxide (ZrSiₓO_{y}) pattern, and wherein the first and second gate oxide layer patterns comprise substantially the same material.

3. The semiconductor device of claim 1, wherein the metal oxide layer pattern comprises an aluminum oxide layer.

4. The semiconductor device of claim 1, wherein the first polysilicon layer pattern is doped with P type impurities, and the second polysilicon layer pattern is doped with N type impurities.

5. The semiconductor device of claim 1, wherein the metal oxide layer comprises a layer that suppresses Fermi level pinning.

6. The semiconductor device of claim 1, wherein the gate oxide layer pattern comprises an oxide of hafnium and/or zirconium.

7. A method of manufacturing a semiconductor device, comprising:
forming a gate oxide layer that includes a high dielectric constant material on a substrate that is divided into a PMOS region and an NMOS region;
forming a metal oxide layer on the gate oxide layer;
forming a silicon nitride layer on the metal oxide layer;
selectively removing the silicon nitride layer and the metal oxide layer in the NMOS region to form a preliminary metal oxide layer pattern and a preliminary silicon nitride layer pattern;
forming a polysilicon layer on the gate oxide layer, the preliminary metal oxide layer pattern and the preliminary silicon nitride layer pattern; and
patterning the polysilicon layer, the preliminary silicon nitride layer pattern, the preliminary metal oxide layer pattern and the gate oxide layer to form a first gate pattern on the PMOS region and a second gate pattern on the NMOS region, the first gate pattern including a first gate oxide layer pattern, a metal oxide layer pattern, a silicon nitride layer pattern and a first polysilicon layer pattern, and the second gate pattern including a second gate oxide layer pattern and a second polysilicon layer pattern.

8. The method of claim 7, wherein forming the gate oxide layer comprises forming at least one of a hafnium oxide (HfO₂) layer, a hafnium oxynitride (HfOₓN_{y}) layer, a hafnium silicon oxynitride (HfSiₓO_{y}N_{z}) layer, a hafnium aluminum oxide (HfAlₓO_{y}) layer, a zirconium oxide (ZrO₂) layer, a zirconium oxynitride (ZrOₓN_{y}) layer, a zirconium silicon oxynitride (ZrSiₓO_{y}N_{z}) layer and/or a zirconium silicon oxide (ZrSiₓO_{y}) layer.

9. The method of claim 7, further comprising curing the gate oxide layer by a thermal treatment process and/or a plasma treatment process.

10. The method of claim 7, wherein forming the metal oxide layer comprises forming an aluminum oxide layer.

11. The method of claim 7, wherein forming the silicon nitride layer comprises forming a silicon nitride layer via an atomic layer deposition (ALD) process using a SiCl₂H₂ (DCS) gas, Si₂Cl₆ (HCD) gas or SiCl₄ gas as a reaction gas.

12. The method of claim 7, wherein selectively removing the silicon nitride layer and the metal oxide layer in the NMOS region to form a preliminary metal oxide layer pattern and a preliminary silicon nitride layer pattern comprises:
forming a photoresist pattern that exposes at least part of the NMOS region on the gate oxide layer, the metal oxide layer and the silicon nitride layer;
etching the silicon nitride layer using the photoresist pattern as an etching mask; and
simultaneously removing the photoresist pattern and the metal oxide layer.

13. The method of claim 7, wherein removing the silicon nitride layer comprises removing the silicon nitride layer by a wet etching process.

14. The method of claim 7, wherein selectively removing the silicon nitride layer and the metal oxide layer in the NMOS region to form a preliminary metal oxide layer pattern and a preliminary silicon nitride layer pattern comprises:
forming a photoresist pattern that exposes at least part of the NMOS region on the gate oxide layer, the metal oxide layer and the silicon nitride layer;
sequentially etching the silicon nitride layer and the metal oxide layer using the photoresist pattern as an etching mask; and
removing the photoresist pattern.

15. The method of claim 7, wherein selectively removing the silicon nitride layer and the metal oxide layer in the NMOS region to form a preliminary metal oxide layer pattern and a preliminary silicon nitride layer pattern comprises:
forming a photoresist pattern that exposes at least part of the NMOS region on the gate oxide layer, the metal oxide layer and the silicon nitride layer;
etching the silicon nitride layer using the photoresist pattern as an etching mask; and
simultaneously removing the photoresist pattern and an exposed portion of the metal oxide layer.

16. The method of claim 7, further comprising:
doping the polysilicon layer on the PMOS region with P type impurities; and
doping the polysilicon layer in the NMOS region with N type impurities.

17. A semiconductor device comprising:
a substrate having a PMOS region and an NMOS region;
a first gate pattern on the PMOS region, the first gate pattern including a first gate oxide layer pattern that comprises an oxide of hafnium and/or zirconium, an aluminum oxide layer pattern, a silicon nitride layer pattern and a first polysilicon layer pattern that is doped with P type impurities that are sequentially stacked on the substrate; and
a second gate pattern on the NMOS region, the second gate pattern including a second gate oxide layer pattern and a second polysilicon layer pattern that is doped with N type impurities that are sequentially stacked on the substrate.

18. The semiconductor device of claim 17, wherein the thickness of the first gate pattern is less than about 50 Angstroms.

19. The semiconductor device of claim 1, wherein the thickness of the first gate pattern is less than about 50 Angstroms.
